(19) United States
(12) Patent Application Publication
(10) Pub. No.: US 2025/0347478 A1
(43) Pub. Date: Nov. 13, 2025

(54) METAL FOAM THERMAL INTERFACE MATERIALS

(71) Applicant: International Business Machines Corporation, Armonk, NY (US)

(72) Inventors: Teddie P. Magbitang, San Jose, CA (US); Krystelle Lionti, San Jose, CA (US); Noel Arellano, Gilroy, CA (US); Rudy J. Wojtecki, San Jose, CA (US)

(21) Appl. No.: 18/661,636

(22) Filed: May 12, 2024

(51) Int. Cl. F28F 3/06; C09K 5/14; C23C 14/04; C23C 14/08; C23C 14/20; C23C 16/04; C23C 16/40; C25D 3/44; C25D 5/02; F28D 21/00

(52) U.S. Cl. CPC F28F 3/06; C09K 5/14; C23C 14/046; C23C 14/081; C23C 14/20; C23C 16/045; C23C 16/403; C25D 3/44; C25D 5/02; F28D 2021/0028; F28F 2255/00

(57) ABSTRACT

Deposit and cure, on a first heat transfer component, a porous organo-silicate material. Fill connected porosity of the deposited and cured porous organo-silicate material with a thermally conductive material. Bond the porous organo-silicate material having the filled connected porosity to a second heat transfer component.

### BACKGROUND

The present invention relates generally to the electrical, electronic and computer arts and, more particularly, to thermal control of electronics and the like.

The semiconductor industry's drive to higher power density in microprocessor chips, and to continued scaling to more dense and exotic architectures, has led to dramatic on-chip heat generation. In order for advanced electronic devices to operate optimally, improved thermal management in advanced electronic packaging has become increasingly important. Conductive heat transfer is commonly used to spread the heat from the point of generation into a heat sink. Thermal interface materials (TIMs) are used to provide a pathway for the heat to move from the source to the heat sink. In addition, TIMs also help minimize thermal contact resistance due to surface roughness of various interfaces. The current generation of TIMs include electrically conductive materials or high dielectric constant materials.

### BRIEF SUMMARY

Principles of the invention provide techniques for metal foam thermal interface materials from the use of porous organics as a sacrificial scaffold. In one aspect, an exemplary method includes depositing and curing, on a first heat transfer component, a porous organo-silicate material; filling connected porosity of the deposited and cured porous organo-silicate material with a thermally conductive material; and bonding the porous organo-silicate material having the filled connected porosity to a second heat transfer component.

In another aspect, an exemplary composition of matter includes a porous organo-silicate material having an interconnected porosity of at least 9% that is filled with a thermally conductive material that is different than the porous organo-silicate material.

In a further aspect, an exemplary apparatus includes a first heat transfer component; a cured porous organo-silicate material on a first side of the first heat transfer component; a thermally conductive material filling connected porosity of the deposited and cured porous organo-silicate material; and a second heat transfer component bonded to the porous organo-silicate material having the filled connected porosity.

In still a further aspect, another exemplary method includes depositing and curing, on a first heat transfer component, a porous organo-silicate material; filling connected porosity of the deposited and cured porous organo-silicate material with a thermally conductive material; removing the porous organo-silicate material, subsequent to the filling, to produce an intermediate structure; and bonding the intermediate structure to a second heat transfer component.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-3 show steps in a first assembly technique, according to an aspect of the invention;

FIGS. 4-9 show steps in a second assembly technique, according to an aspect of the invention;

FIG. 10 shows a scanning electron microscope (SEM) image of porous oxycarbosilane with platinum fill, in accordance with aspects of the invention;

FIGS. 11-13 show three additional images obtained by bright field transmission electron microscopy (BF TEM), in accordance with aspects of the invention;

FIG. 14 presents energy-dispersive X-ray spectroscopy (EDS) data showing Pt presence in a film), in accordance with aspects of the invention;

FIGS. 15 and 16 present an example with zinc oxide, in accordance with aspects of the invention;

FIGS. 17 and 18 present Electron Energy Loss Spectroscopy (EELS) mapping to show components penetrating through the porous layer, in accordance with aspects of the invention;

FIGS. 19 and 20 present additional EELS data for a POCS film filled with ALD ZnO, in accordance with aspects of the invention;

FIGS. 21 and 22 present still more EELS data for the POCS film filled with ALD ZnO, in accordance with aspects of the invention; and

FIG. 23 shows FIG. 2 after removing the porous organo-silicate matrix.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein, it will be appreciated that in one aspect, an exemplary method includes depositing and curing, on a first heat transfer component, a porous organo-silicate material; filling connected porosity of the deposited and cured porous organo-silicate material with a thermally conductive material; and bonding the porous organo-silicate material having the filled connected porosity to a second heat transfer component. Technical benefits include enhancing heat transfer with an approach that is compatible with current microelectronic processes and tooling.

Non-limiting examples of heat transfer components include heat sinks, heat spreaders, cold plates, heat pipes, reflux boilers, vapor chambers, and the like.

Some embodiments further include allowing overburden of the thermally conductive material to accumulate on a surface of the first heat transfer component, where the bonding includes using the overburden to bond the surface of the first heat transfer component to the second heat transfer component. Technical benefits include further enhancing heat transfer and bonding.

In some instances, the depositing and curing of the porous organo-silicate material includes using a sol-gel process. Technical benefits include providing the enhanced heat transfer with a readily available deposition process.

The filling can include filling with an electrically conductive material, such as aluminum, or filling with an electrically insulating material, such as aluminum oxide (e.g. Al₂O₃). Technical benefits include providing enhanced heat transfer with electrical conducting or insulating properties as appropriate for a given application.

The filling can be carried out with, for example, with atomic layer deposition (ALD), chemical vapor deposition (CVD), physical vapor deposition (PVD), electro chemical deposition, or liquid phase casting. Technical benefits include providing the enhanced heat transfer with a readily available filling process.

In some cases, the first heat transfer component includes a finned heat sink and the second heat transfer component includes a heat spreader. Technical benefits include providing the enhanced heat transfer for this particularly useful packaging case.

In some cases, a first side of the second heat transfer component faces the first heat transfer component after the bonding, and the method further includes depositing and curing, on a second side of the second heat transfer component, another porous organo-silicate material (which, in general, could be the same as, or different than, the porous organo-silicate material applied to the first heat transfer component); filling connected porosity of the deposited and cured other porous organo-silicate material with other thermally conductive material (which, in general, could be the same as, or different than, the thermally conductive material filled into the porous organo-silicate material applied to the first heat transfer component); and bonding the other porous organo-silicate material having the filled connected porosity to an additional component. For example, the first heat transfer component includes a finned heat sink, the second heat transfer component includes a heat spreader, and the additional component includes a chip. Technical benefits include providing the enhanced heat transfer for this more complex packaging case.

We have observed interconnected porosity for porous oxycarbosilane (POCS) as low as 9% porous volume; thus, in some instances, subsequent to the depositing and curing, the porous organo-silicate material has an interconnected porosity of at least 9%. Note however that other embodiments could have other values; for example, the porous organo-silicate material could have an interconnected porosity of at least 50%. Technical benefits include providing the enhanced heat transfer with a manufacturable porous material.

In some cases, in the depositing and curing step, the porous organo-silicate material includes porous oxycarbosilane (POCS). Technical benefits include providing the enhanced heat transfer with a readily available porous material.

In another aspect, an exemplary composition of matter includes a porous organo-silicate material having an interconnected porosity of at least 9% that is filled with a thermally conductive material that is different than the porous organo-silicate material. It is believed that other porous insulating materials could include expanded polystyrene or polyurethane foam; and again, other embodiments could have other values for porosity; for example, the porous organo-silicate material could have an interconnected porosity of at least 50%. Technical benefits include the provision of a conforming, highly thermal conductive nanocomposite thermal interface material including a porous electronically insulating scaffold and highly thermally conductive refill material.

In still another aspect, an exemplary apparatus includes: a first heat transfer component; a cured porous organo-silicate material on a first side of the first heat transfer component; a thermally conductive material filling connected porosity of the deposited and cured porous organo-silicate material; and a second heat transfer component bonded to the porous organo-silicate material having the filled connected porosity. Technical benefits include enhancing heat transfer with an approach that is compatible with current microelectronic processes and tooling.

One or more embodiment further include overburden of the thermally conductive material between the first and second heat transfer components. Technical benefits include further enhancing heat transfer and bonding.

In some cases, the first heat transfer component includes a finned heat sink and the second heat transfer component includes a heat spreader. Technical benefits include providing the enhanced heat transfer for this particularly useful packaging case.

In some cases, a first side of the second heat transfer component faces the first side of the first heat transfer component, and the apparatus further includes other cured porous organo-silicate material on a second side of the second heat transfer component (which, in general, could be the same as, or different than, the porous organo-silicate material applied to the first heat transfer component); other thermally conductive material filling connected porosity of the other porous organo-silicate material (which, in general, could be the same as, or different than, the thermally conductive material filled into the porous organo-silicate material applied to the first heat transfer component); and an additional component bonded to the other porous organo-silicate material having the filled connected porosity. For example, the first heat transfer component includes a finned heat sink, the second heat transfer component includes a heat spreader, and the additional component includes a chip. Technical benefits include providing the enhanced heat transfer for this more complex packaging case.

As noted, we have observed interconnected porosity for porous oxycarbosilane (POCS) as low as 9% porous volume; thus, in some instances, the cured porous organo-silicate material has an interconnected porosity of at least 9%. Note however that other embodiments could have other values; for example, the cured porous organo-silicate material could have an interconnected porosity of at least 50%. Technical benefits include providing the enhanced heat transfer with a manufacturable porous material.

In a further aspect, an exemplary method includes: depositing and curing, on a first heat transfer component, a porous organo-silicate material; filling connected porosity of the deposited and cured porous organo-silicate material with a thermally conductive material; removing the porous organo-silicate material, subsequent to the filling, to produce an intermediate structure; and bonding the intermediate structure to a second heat transfer component. Removing the porous organo-silicate material includes, for example, applying a selective chemical etching process. Technical benefits include a system that has the indicated benefits of the various embodiments and additionally will advantageously be less stiff and more compliant after matrix removal, with the added compliance reducing thermal contact resistance.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
A thermal management system implementing a conforming, highly thermal conductive nanocomposite thermal interface material including a porous electronically insulating scaffold and highly thermally conductive refill material, with partial or complete pore refill with or without over burden;
Superior electrical insulating properties while maximizing heat transfer from the heat source to the heat sink;
Approach that is fully compatible with current microelectronic processes and tooling;
A process flow that provides a drop-in solution using current advanced chip integration processes for improved thermal management in state of the art electronic packages.

As noted above, the semiconductor industry's drive to higher power density in microprocessor chips, and continued scaling to more dense and exotic architectures, has led to dramatic on-chip heat generation. In order for advanced electronic devices to operate optimally, improved thermal management in advanced electronic packaging has become increasingly important. Conductive heat transfer is commonly used to spread the heat from the point of generation into a heat sink. Thermal interface materials (TIMs) are used to provide a pathway for the heat to move from the source to the heat sink. In addition, TIMs also help minimize thermal contact resistance due to surface roughness of various interfaces. The current generation of TIMs include electrically conductive materials or high dielectric constant materials. For electronic packaging applications, one or more embodiments advantageously provide a TIM with high thermal conductivity and low electrical conductivity.

In the development of thermal interface materials, a strategy to maximize thermal conductivity (k) is often pursued with composites, where a highly thermally conductive filler is used in combination with a polymer matrix. In this composite, the loading, aspect ratio, and size of the filler is relied on for the thermal conductivity of the TIM material and the polymer merely provides adhesion and mechanical stability to the film. State of the art gel-based TIM materials are composite materials including 90-96% by weight spherical filler material of different sizes to ensure efficient packing, such that interstitial spacing between filler particles is minimized. The thermal conductivity realized in these composite materials is significantly lower than the bulk filler material. For instance, aluminum can have a thermal conductivity of up to 250 W/m·K, but use in composite TIM materials only demonstrates a thermal conductivity of 4 W/m·K. In the cured film, the thermal resistance originates from the matrix polymer, which is orders of magnitude lower in thermal conductivity (e.g., 0.16 W/m·K). In the design of high-performance TIMs, the matrix polymer is a pertinent component to optimize, and therefore improve, the thermal conductivity of a composite material. One or more embodiments advantageously employ an organic porous material as a scaffold, where a highly thermally conductive material (such as a metal or metal oxide) is deposited onto the surface to form a percolating network. This material therefore has the potential to overcome the limitations of gel-based TIM materials that are limited in performance by their matrix polymer.

One or more embodiments advantageously employ porous organo-silicates (such as porous oxycarbosilane (POCS)) with excellent electrically insulating properties as a novel TIM scaffold. Porous organo-silicates with interconnected pores can be refilled with highly thermally conductive materials, yielding a nanocomposite that can take advantage of the bulk thermal conductivity of the scaffold's surface coating. The conductive material can be deposited/filled by atomic layer deposition (ALD), chemical vapor deposition (CVD), physical vapor deposition (PVD), electro chemical deposition, liquid phase casting, or the like. The porous organo-silicates can be directly deposited/applied on one interface followed by the refill process, then bonded to the chip interface. To ensure good adhesion, the bonding can include reflowing the overburden of the fill material or can use a bonding agent.

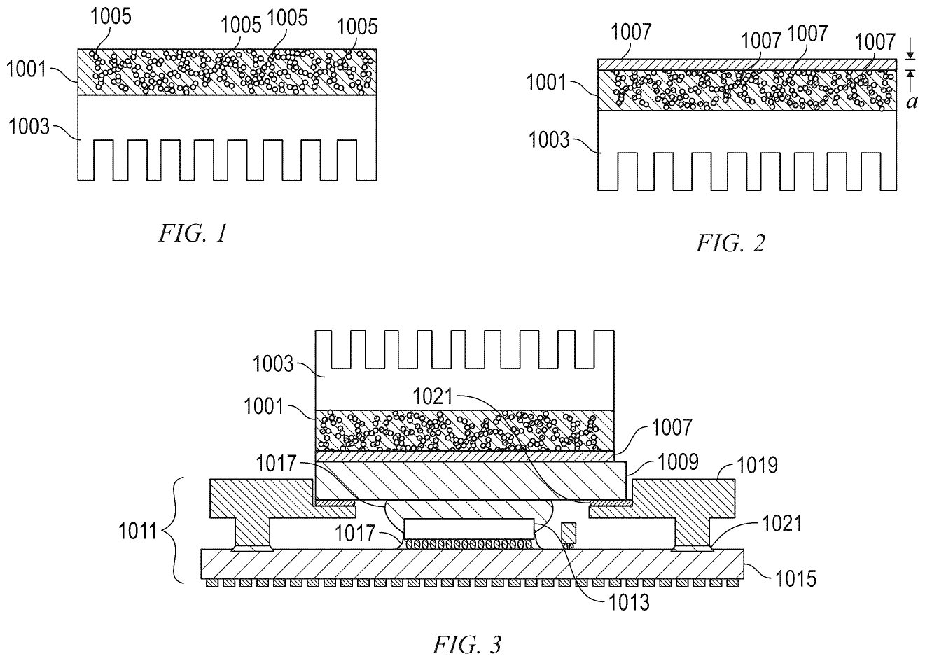

FIGS. 1-3 show a first exemplary process flow. In FIG. 1 deposit and cure porous organo-silicates 1001 on a heat sink 1003; note the voids 1005 (porosity). The heat sink can have fins (depicted but not separately numbered) for forced or free convection to air or another cooling fluid (gas or liquid). In FIG. 2, refill the porosity with thermally conductive material 1007 with overburden of thickness a. In FIG. 3, bond (using reflow of the overburden or with a bonding agent) the heat sink with the heat spreader 1009 of the electronic package 1011. Note the chip 1013 and laminate 1015. Also, note that an advantage of the overburden is that when the parts are assembled, the contact on the interface is enhanced as compared to a case without overburden.

Thus, a pertinent aspect in one or more embodiments is the use of an organo-silicate scaffold which is electrically insulating, has good porosity, and can be back-filled with interesting materials, such as one or more highly thermally conductive materials, in order to facilitate heat flow from a heat source to a heat sink. In one or more embodiments, the back-filled scaffold can be tailored to provide compliance/conformance at the interface.

We have found that a porosity of about 50% can be achieved, with a pore size of about 8 nm. The organic insulating scaffold can be produced, for example, by a sol-gel process. The skilled artisan will be familiar with known sol-gel processes.

Referring to FIG. 3, in addition to the laminate circuit board 1015, chip 1013 (which is connected to the board 1015 by controlled collapse chip connection (C4) or the like, not separately numbered), heat spreader 1009, and porous organo-silicates 1001 filled with thermally conductive material 1007 with overburden, note the underfill 1017 around the C4 solder blobs and between the chip and the circuit board. In some cases, the underfill 1017 between the heat spreader 1009 and the chip 1013 may not be thermally conductive, and is provided primarily for structural stability. As discussed below, it could also be replaced with TIM according to aspects of the invention. Heat spreader 1009 can be made of aluminum or another suitable metal with good thermal conductivity. It can optionally be supported by a support/enclosure 1019 made of copper or other suitable metal and can be secured/sealed with adhesive/scaler 1021.

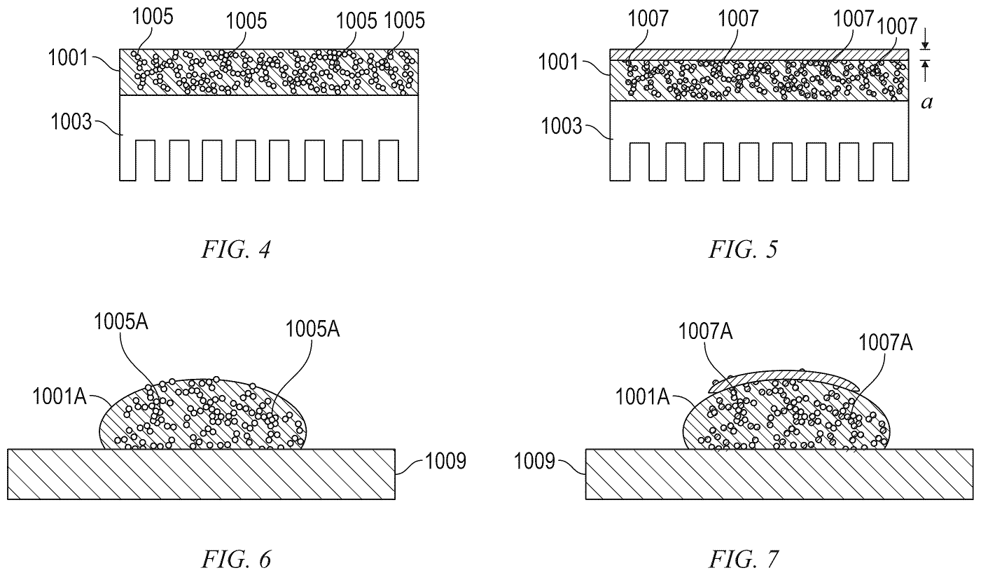

FIGS. 4-9 show a second exemplary process flow, wherein an exemplary inventive TIM is used both between the chip and spreader and between the heat spreader and the heat sink. In FIG. 4 deposit and cure porous organo-silicates 1001 on a heat sink 1003; note the voids 1005 (porosity). The heat sink can have fins (depicted but not separately numbered) for forced or free convection to air or another cooling fluid. In FIG. 5, refill the porosity with thermally conductive material 1007 with overburden of thickness a.

In FIG. 6 deposit and cure porous organo-silicates 1001A on a heat spreader 1009; note the voids 1005A (porosity). In FIG. 7, refill the porosity with thermally conductive material 1007A with overburden (not separately numbered).

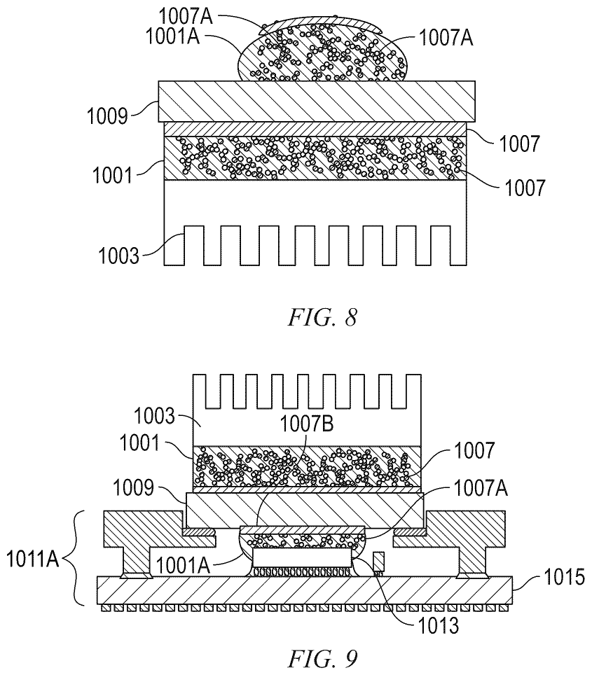

In FIG. 8, bond the heat sink 1003 and heat spreader 1009 to create a thermal management assembly (TMA).

In FIG. 9, bond the TMA to an electronic package 1011A, also referred to as a chip and laminate assembly. The overburden of material 1007A has spread out during assembly and is numbered 1007B.

One or more embodiments thus provide a nanocomposite thermal interface material (TIM), including a porous organic insulating scaffold, with interconnected porosity, and filled partially or completely with a high thermal conductivity material. In some instances, the organic insulating scaffold material is produced by a sol-gel process. In one or more instances, deposit a thermally conductive filler (such as Al or AlO₃) to fill the pores; this filler can be electrically conductive or electrically insulating. The filler can be deposited, for example, via ALD, CVD, PVD, electro chemical deposition, liquid phase casting, or the like.

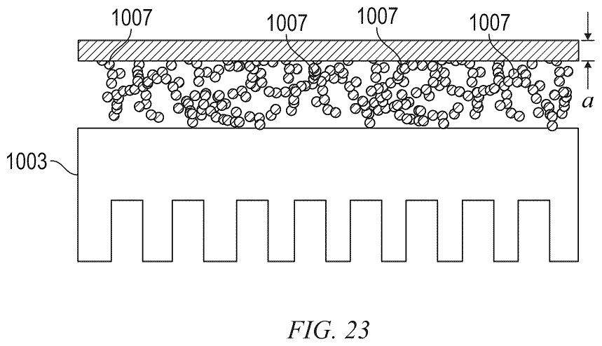

In some instances, an inorganic thin film adhesion layer, such as indium, can be added after the sol-gel process. In one or more exemplary embodiment, indium is a fill metal process and the adhesion layer is an overburden of the filling. In some cases, the sol-gel process leaves an overburden on the scaffold surface to facilitate surface bonding. Optionally, the porous organo-silicates can be removed after refill (for example, using a selective chemical etching process)—the system will be less stiff and more compliant after matrix removal. FIG. 23 shows FIG. 2 after removing the porous organo-silicate matrix. The nanocomposite TIM in accordance with aspects of the invention can be applied in many different locations/applications; for example, between the heat source (chip) and the heat sink and/or between a heat spreader and the heat sink.

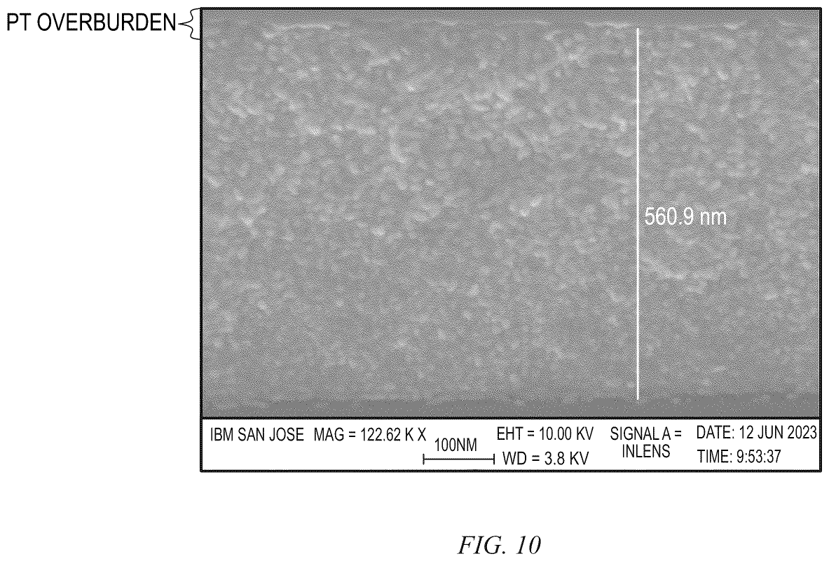

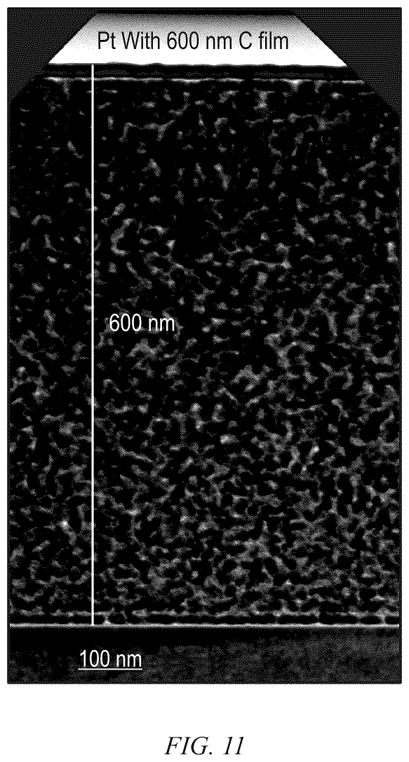

FIG. 10 shows a scanning electron microscope (SEM) image of porous oxycarbosilane with platinum fill all the way through the film—the image is a cross section of a film about 560.9 nm. It is seen to be homogeneous with Pt throughout. The uniform gray material at the top is Pt overburden.

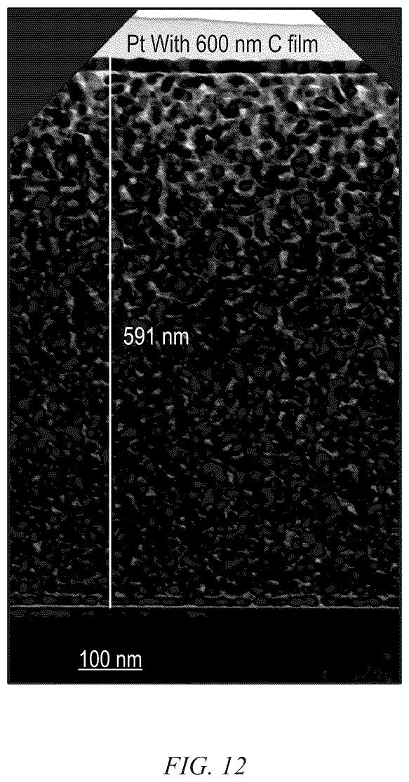

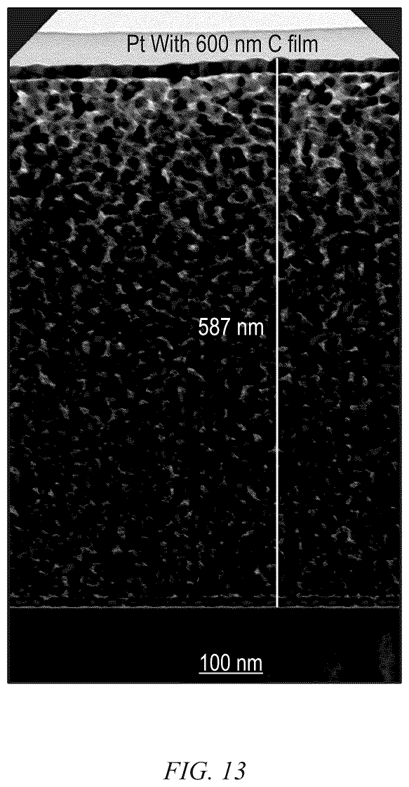

FIGS. 11-13 show three additional images obtained by bright field transmission electron microscopy (BF TEM); the sample is POCS with ALD Pt present throughout the film thickness, with additional overburden. The three films in FIGS. 11-13 respectively have thicknesses of about 600 nm, about 591 nm, and about 587 nm.

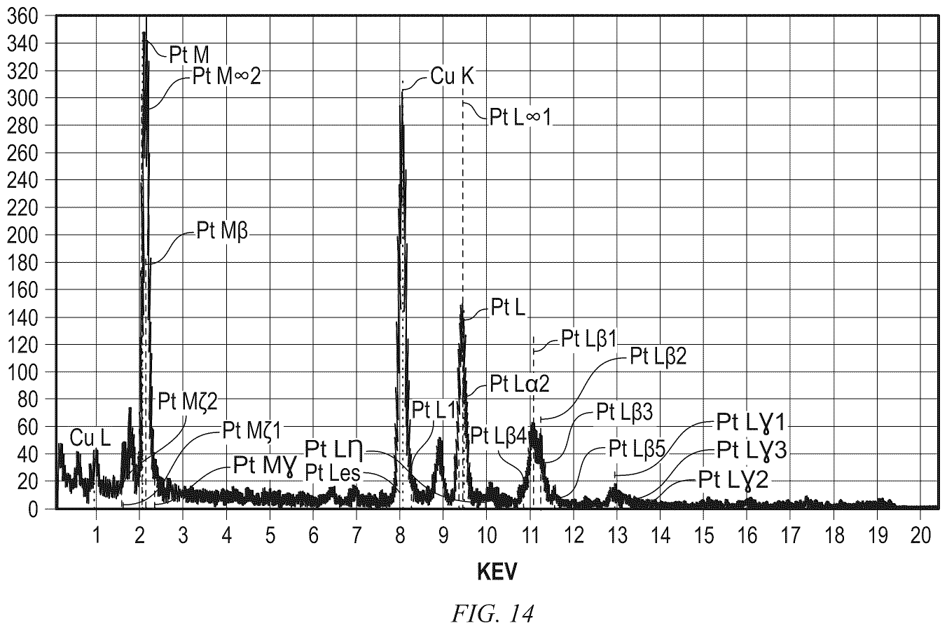

FIG. 14 presents energy-dispersive X-ray spectroscopy (EDS) data showing Pt presence in the film (Pt is present through the entire film thickness). The Cu signal comes from the TEM grid.

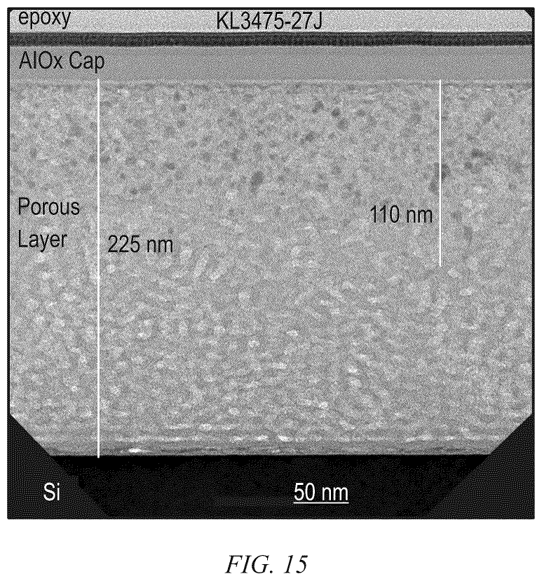

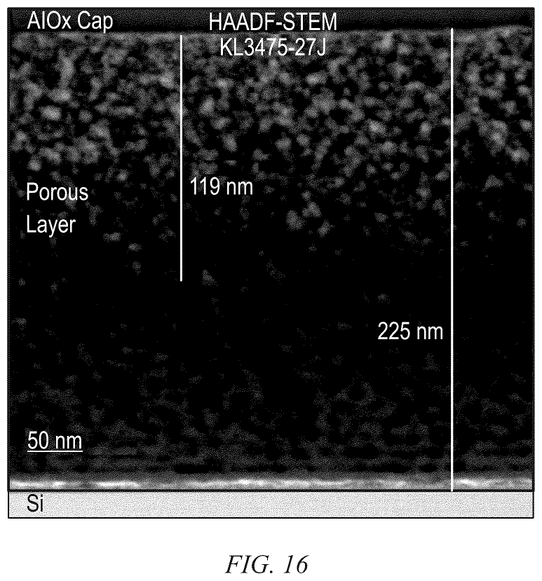

FIGS. 15 and 16 present an example with zinc oxide; specifically, a POCS film filled with ALD ZnO (50 deposition cycles). FIG. 15 is a BF TEM image while FIG. 16 is a high-angle annular dark-field scanning transmission electron microscopy (HAADF-STEM) image of the same sample. The porous layer is about 225 nm thick. ZnO is observed to have penetrated the porous layer up to ˜110 nm in FIG. 15 and up to ˜119 nm in FIG. 16. The bottom of the film is not infiltrated with ZnO. Note, however, that this is a non-limiting example and it is believed that by changing the conditions complete infiltration could have been achieved. The Si substrate can be seen in both FIGS. 15 and 16, as can the aluminum oxide (AlOₓ/Al₂O₃) cap. An upper epoxy layer can also be seen in FIG. 15. In FIG. 16, it is believed that that the porosity at the POCS/substrate interface is oriented differently and more prone to precursor infiltration.

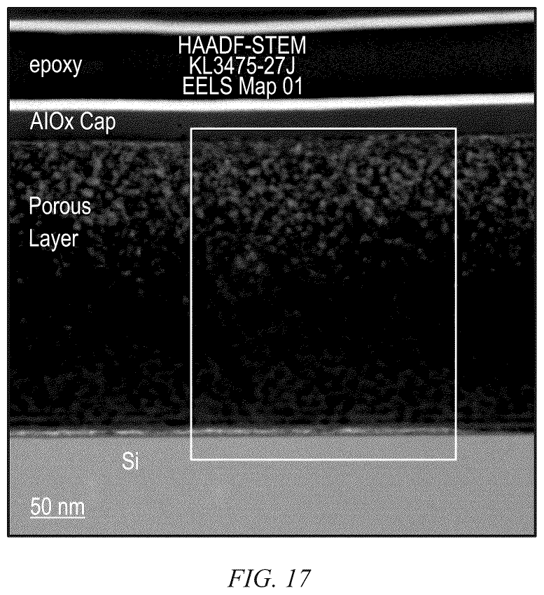

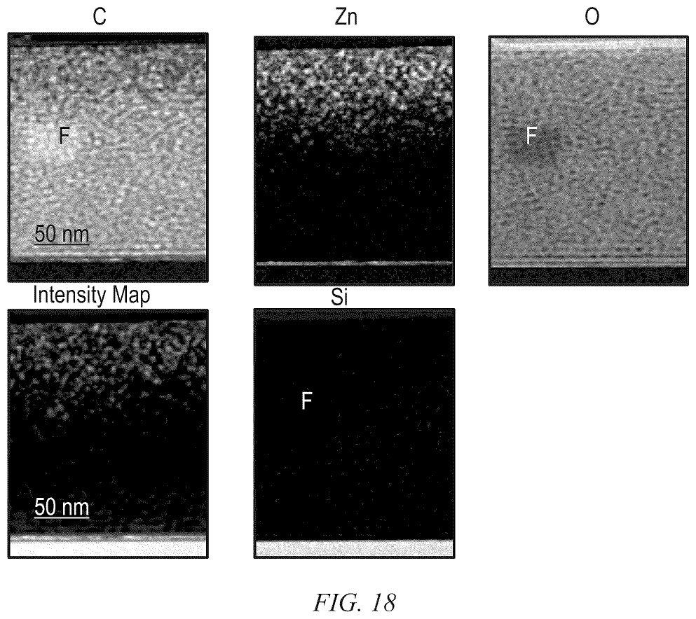

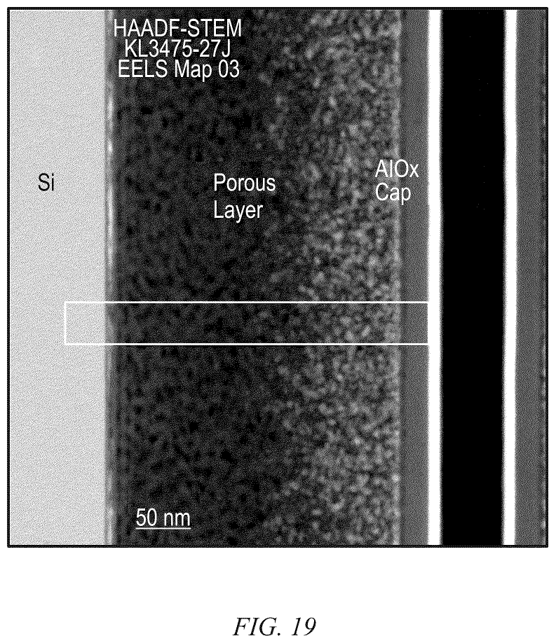

FIGS. 17 and 18 present Electron Energy Loss Spectroscopy (EELS) mapping to show what components are penetrating through the porous layer, for the POCS film filled with ALD ZnO (50 deposition cycles). It can be seen in FIG. 17 that the ZnOx did penetrate the porous layer. FIG. 18 shows corresponding EELS elemental maps (temperature mode) for C, Zn, O, and Si, as well as an intensity map (an EELS maps where taken in “temperature mode”; thus, the intensity is proportional to the amount of individual element present within the POCS matrix). The region labeled “F” was used to focus, which caused slight loss of O and Si and slight gain of C.

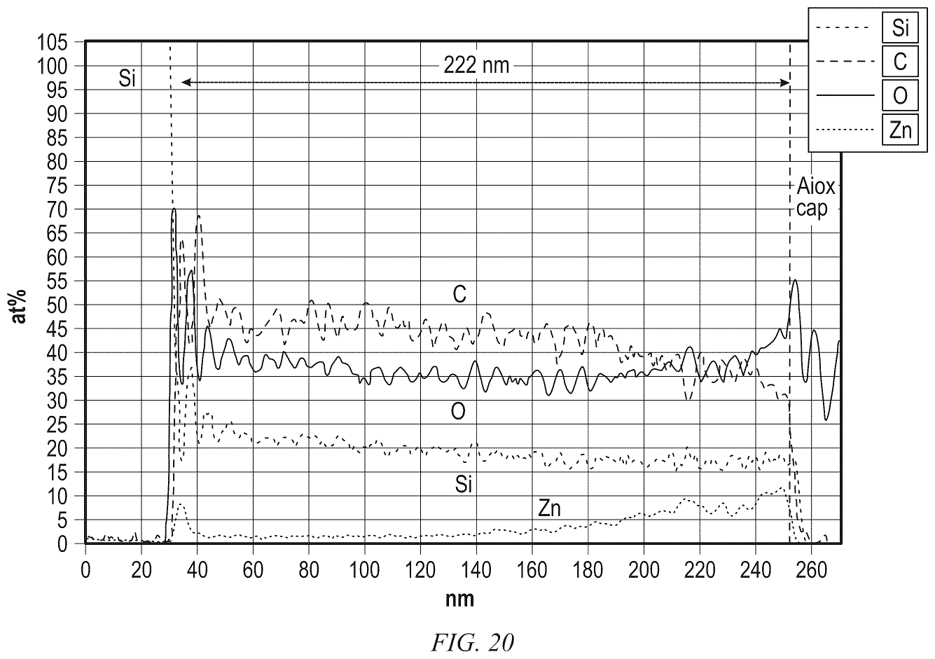

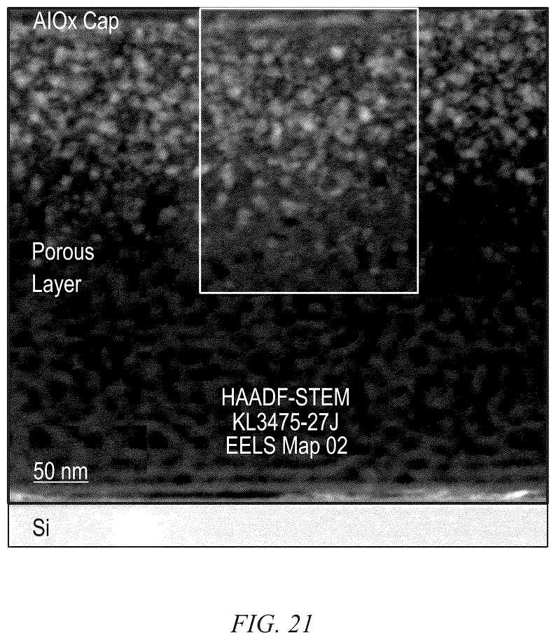

FIGS. 19 and 20 present additional EELS data for the POCS film filled with ALD ZnO (50 deposition cycles). As seen in FIG. 19, Zn penetrated the entire porous layer but was concentrated as ZnOx particles in the top ˜110 nm. FIG. 20 presents quantified EELS elemental profiles for Zn, Si, O, and C. The concentration of Zn is not very high in this sample; the maximum zinc concentration Znmax≤˜10 at % (atomic percentage). N is not observed in this sample.

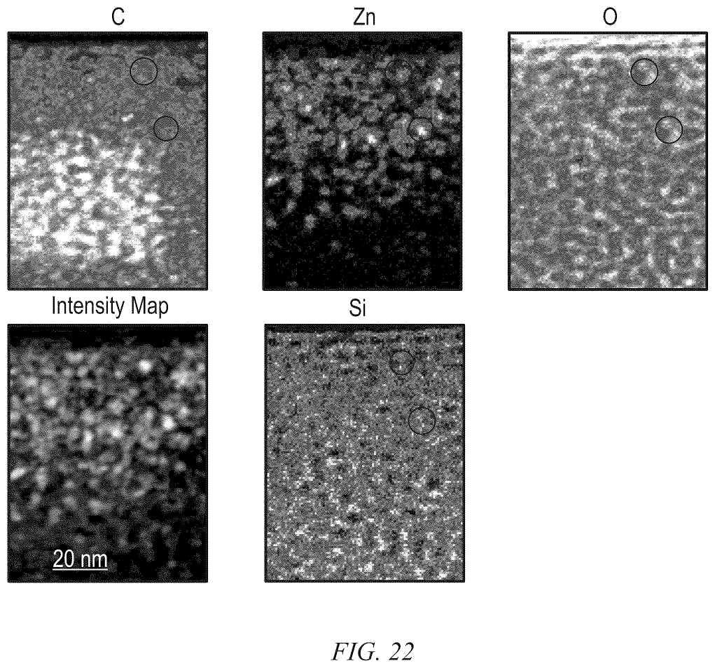

FIGS. 21 and 22 present still more EELS data for the POCS film filled with ALD ZnO (50 deposition cycles). As seen in FIG. 21, ZnOx did penetrate the porous layer (the boxed area in FIG. 21 illustrates the extent to which ZnOx was deposited into the POCS matrix, with unoptimized conditions, with the understanding that no attempt for optimization was made in the non-limiting example of FIG. 21). FIG. 22 shows corresponding EELS elemental maps (temperature mode) for C, Zn, O, and Si, as well as an intensity map (EELS maps where taken in “temperature mode”; thus, the intensity is proportional to the amount of individual element present with in the POCS matrix). The circled particles are brighter in Zn and O.

It is worth noting that one or more embodiments do not require aligning nanofibers in the direction of heat flow. One or more embodiments provide an electronically insulative porous scaffold with the porosity filled with thermally conductive material.

Further comments are now provided regarding porosity and the interconnectivity of the porous regions. Porous volume can be derived, for example, by BET (Brunauer-Emmett-Teller a technique to measure porosity) or Ellipsometric Porosimetry (EP). The latter measures the change of the optical properties and thickness of the materials during adsorption and desorption of a volatile species either at atmospheric pressure (EPA), or under reduced pressure (EP), depending on the application. Because the thermally conductive material has to infiltrate the porosity to be measured, the interconnected porosity is what will be measured by BET or EP. It is possible that there may be some pores in the scaffold that are isolated and into which the thermally conductive material cannot infiltrate. It is the connected/not isolated porosity that is of interest in one or more embodiments. However, if it was desired for some reason to measure isolated porosity, density ratios can be used. It should be noted that BET is often impractical for highly porous thin films; thus, one or more embodiments employ EP as a method to measure porous volume. Again, in one or more embodiments, connected porosity is pertinent and isolated porosity does not play a role.

Given the teachings herein, for any elements for which example materials are not set forth, the skilled artisan can select appropriate materials, and for any fabrication steps for which specific exemplary processes have not been set forth, the skilled artisan can select appropriate known processes. Bulk silicon is a non-limiting example of a suitable substrate material, other materials are also possible.

Although the overall fabrication method and the structures formed thereby are novel, certain individual processing steps required to implement the method may utilize conventional techniques and/or tooling familiar to the skilled artisan in the field of electronics packaging. These techniques and tooling will already be familiar to one having ordinary skill in the relevant arts given the teachings herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in integrated circuit chips may not be explicitly shown in a given figure for case of explanation. This does not imply that the semiconductor layer(s) not explicitly shown are omitted in the actual device.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A method comprising:
depositing and curing, on a first heat transfer component, a porous organo-silicate material;
filling connected porosity of the deposited and cured porous organo-silicate material with a thermally conductive material; and
bonding the porous organo-silicate material having the filled connected porosity to a second heat transfer component.

2. The method of claim 1, further comprising allowing overburden of the thermally conductive material to accumulate on a surface of the first heat transfer component, wherein the bonding comprises using the overburden to bond the surface of the first heat transfer component to the second heat transfer component.

3. The method of claim 2, wherein the depositing and curing of the porous organo-silicate material comprises using a sol-gel process.

4. The method of claim 3, wherein the filling step comprises filling with an electrically conductive material.

5. The method of claim 4, wherein the electrically conductive material comprises aluminum.

6. The method of claim 3, wherein the filling step comprises filling with an electrically insulating material.

7. The method of claim 6, wherein the electrically insulating material comprises aluminum oxide.

8. The method of claim 3, wherein the filling is carried out with atomic layer deposition (ALD).

9. The method of claim 3, wherein the filling is carried out with chemical vapor deposition (CVD).

10. The method of claim 3, wherein the filling is carried out with physical vapor deposition (PVD).

11. The method of claim 3, wherein the filling is carried out with electro chemical deposition.

12. The method of claim 3, wherein the filling is carried out with liquid phase casting.

13. The method of claim 1, wherein the first heat transfer component comprises a finned heat sink and wherein the second heat transfer component comprises a heat spreader.

14. The method of claim 1, wherein a first side of the second heat transfer component faces the first heat transfer component after the bonding, further comprising:
depositing and curing, on a second side of the second heat transfer component, another porous organo-silicate material;
filling connected porosity of the deposited and cured other porous organo-silicate material with other thermally conductive material; and
bonding the other porous organo-silicate material having the filled connected porosity to an additional component.

15. The method of claim 14, wherein: the first heat transfer component comprises a finned heat sink, the second heat transfer component comprises a heat spreader, and the additional component comprises a chip.

16. The method of claim 1, wherein, subsequent to the depositing and curing, the porous organo-silicate material has an interconnected porosity of at least 9%.

17. The method of claim 1, wherein, in the depositing and curing step, the porous organo-silicate material comprises porous oxycarbosilane (POCS).

18. A composition of matter comprising a porous organo-silicate material having an interconnected porosity of at least 9% that is filled with a thermally conductive material that is different than the porous organo-silicate material.

19. An apparatus comprising:
a first heat transfer component;
a cured porous organo-silicate material on a first side of the first heat transfer component;
a thermally conductive material filling connected porosity of the deposited and cured porous organo-silicate material; and
a second heat transfer component bonded to the porous organo-silicate material having the filled connected porosity.

20. The apparatus of claim 19, further comprising overburden of the thermally conductive material between the first and second heat transfer components.

21. The apparatus of claim 20, wherein the first heat transfer component comprises a finned heat sink and wherein the second heat transfer component comprises a heat spreader.

22. The apparatus of claim 19, wherein a first side of the second heat transfer component faces the first side of the first heat transfer component, further comprising:
other cured porous organo-silicate material on a second side of the second heat transfer component;
other thermally conductive material filling connected porosity of the other porous organo-silicate material; and
an additional component bonded to the other porous organo-silicate material having the filled connected porosity.

23. The apparatus of claim 19, wherein the cured porous organo-silicate material has an interconnected porosity of at least 9%.

24. A method comprising:
depositing and curing, on a first heat transfer component, a porous organo-silicate material;
filling connected porosity of the deposited and cured porous organo-silicate material with a thermally conductive material;
removing the porous organo-silicate material, subsequent to the filling, to produce an intermediate structure; and
bonding the intermediate structure to a second heat transfer component.

25. The method of claim 24, wherein removing the porous organo-silicate material comprises applying a selective chemical etching process.
